(19) United States
(12) Patent Application Publication
(10) Pub. No.: US 2013/0257271 A1
(43) Pub. Date: Oct. 3, 2013

(54) CABLE FIXING APPARATUS, PRINTED CIRCUIT BOARD ASSEMBLY, ELECTRONIC CONTROLLER AND LIGHT-EMITTING DEVICE

(71) Applicant: OSRAM GMBH, Muenchen (DE)

(72) Inventors: Jianbo Gao, Guangzhou City (CN); Haixuan Lin, Guangzhou City (CN); Qing Miao, Guangzhou City (CN); Wengen Tan, Guangzhou City (CN)

(73) Assignee: OSRAM GmbH, Muenchen (DE)

(21) Appl. No.: 13/852,010

(22) Filed: Mar. 28, 2013

(30) Foreign Application Priority Data
Mar. 30, 2012 (CN) 201220131653.X

(51) Int. Cl. H01B 17/00; H05K 1/18; H05K 1/02

(52) U.S. Cl. CPC H01B 17/00; H05K 1/02; H05K 1/181
USPC 315/51; 174/135; 174/250; 361/760

(57) ABSTRACT

The present patent application discloses a cable fixing apparatus, and the cable fixing apparatus includes: at least one slot structure, for holding a cable; and clipping parts at both sides of each slot structure, wherein at least one of the clipping parts has an elasticity enhancement structure, and the elasticity enhancement structure is configured so that the elasticity of the clipping part is enhanced. The present patent application also discloses a printed circuit board assembly (PCBA), an electronic controller (ECG) and a light-emitting device. By using a cable fixing apparatus provided according to embodiments of the present patent application, the cable can be fixed reliably, and/or the costs of a cable fixing apparatus can be lowered.

### RELATED APPLICATIONS

The present application claims priority from Chinese application No.: 201220131653.X filed on Mar. 30, 2012.

### TECHNICAL FIELD

The present patent application relates to the technical field relating to mechanical fixing of a component, specifically, to a cable fixing apparatus, a printed circuit board assembly using the cable fixing apparatus to fix its cables, an electronic controller (e.g., electronic ballast) having at least some of its circuit elements arranged on the printed circuit board assembly, and a light-emitting device including and driven by such an electronic ballast.

### BACKGROUND

Cable fixing is needed in a vast range of fields. For example, an electronic controller such as electronic ballast may sometimes be assembled with an input/output (I/O) wire instead of a terminal; and normally an end of the I/O wire needs to be fixed onto a printed circuit board assembly (PCBA) in the electronic controller, so that the end of the I/O wire will not be loosened off during safety testing and functional testing.

In the prior art, the mechanical components for fixing a cable can be classified into two types.

One type of mechanical component fixes the cable by an upper casing and a lower casing that are fitted with each other; and the cable is fixed in a locating ring formed by the upper casing and the lower casing. However, the mechanical component formed by the upper casing and the lower casing has an elasticity so low that the cable cannot be fixed tightly enough in the case of clearance fit and that it is difficult for the cable to be assembled into the locating ring in the case of interference fit.

The other type of mechanical component is bushing; however using a bushing to fix the cable has the drawbacks of high costs and installation difficulty.

### SUMMARY

Therefore, it is desired to provide an improved cable fixing apparatus. In addition, it is also desired to provide a printed circuit board assembly using the cable fixing apparatus to fix its cables, an electronic controller (e.g., electronic ballast) having at least some of its circuit elements arranged on the printed circuit board, and a light-emitting device including and driven by such an electronic ballast.

According to an embodiment of the present patent application, a cable fixing apparatus is provided, wherein the cable fixing apparatus includes: at least one slot structure, for holding a cable; and clipping parts at both sides of each slot structure, wherein at least one of the clipping parts has an elasticity enhancement structure, and the elasticity enhancement structure is configured so that the elasticity of the clipping part is enhanced.

In the cable fixing apparatus described above, two adjacent slot structures may share the same clipping part. Preferably, the elasticity enhancement structure is a hole-like structure arranged in the clipping part, or the elasticity enhancement structure is constituted by at least one portion of the clipping part, the thickness of which is smaller than that of portions of the clipping part other than the at least one portion. In addition, preferably, at least one of the sides of at least one of the clipping parts that correspond to the slot structure includes at least one locking structure, and the locking structure is configured so as to make it difficult for the cable held in the slot structure to slip out of the slot structure without blocking the cable from entering the slot structure.

According to an embodiment of the present patent application, a printed circuit board assembly is also provided, wherein a cable of the printed circuit board assembly is configured to be fixed by the cable fixing apparatus described above.

According to an embodiment of the present patent application, an electronic controller is also provided, wherein at least some of the circuit components in the electronic controller are arranged on the printed circuit assembly described above. Preferably, the electronic controller is an electronic ballast.

According to an embodiment of the present patent application, a light-emitting device is also provided, wherein the light-emitting device includes an electronic ballast for driving the light-emitting device, and the electronic ballast is configured to be an electronic ballast as described above.

By using a cable fixing apparatus provided according to embodiments of the present patent application, the cable can be fixed reliably, and/or the costs of a cable fixing apparatus can be lowered.

### BRIEF DESCRIPTION OF THE DRAWINGS

The above and other objects, features and advantages of the present patent application will become more apparent from the description below of the principle and preferred embodiments and accompanying drawings of the present patent application. Among the accompanying drawings:

FIG. 1 is a three-dimensional view of an electronic ballast according to an embodiment of the present patent application;

FIG. 2 is an exploded view of an electronic ballast according to an embodiment of the present patent application;

FIG. 3 is a schematic diagram illustrating a cable fixing apparatus according to an embodiment of the present patent application; and

FIGS. 4A to 4D are schematic diagrams illustrating alternatives of a locking structure of a cable fixing apparatus according to an embodiment of the present patent application.

### DETAILED DESCRIPTION

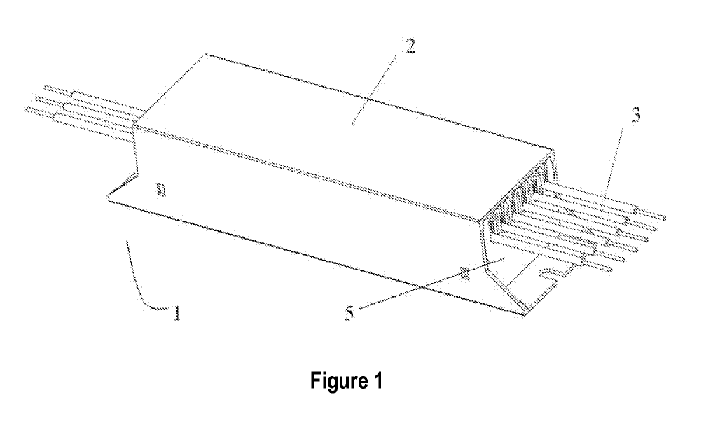

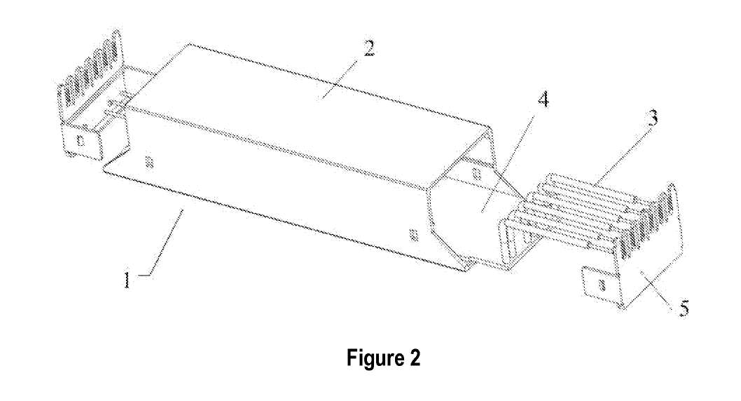

FIG. 1 and FIG. 2 show an example of an electronic ballast 1 according to an embodiment of the present patent application. FIG. 1 is a three-dimensional view of an assembled electronic ballast 1; and FIG. 2 is an exploded view of the electronic ballast.

The electronic ballast 1 includes a casing 2, a cable 3, a PCBA 4 (shown in FIG. 2 only) and a cable fixing apparatus 5. As shown in FIG. 1 and FIG. 2, the cable 3 is connected to the PCBA 4 and fixed onto the PCBA 4 by the cable fixing apparatus 5. The cable fixing apparatus 5 is connected to the casing 2 so that the PCBA 4 is enclosed inside the casing 2. Although the cable 3 is shown as a component independent of the PCBA 4 in FIG. 2, those skilled in the art will appreciate that the cable 3 could be a part of the PCBA 4.

Those skilled in the art will appreciate that FIG. 1 and FIG. 2 are merely schematic diagrams of the electronic ballast, and the electronic ballast may be configured into other forms. Other components with the same or similar functions may be used in place of the components shown in FIG. 1 and FIG. 2, there may be components other than those shown in FIG. 1 and FIG. 2, and the assembling method and connection relation between the components may also be determined according to the actual situation.

Those skilled in the art will appreciate that the electronic ballast shown in FIG. 1 and FIG. 2 may be included in a light-emitting device to drive the light-emitting device. As a matter of course, the electronic ballast shown in FIG. 1 and FIG. 2 may also be applied to other devices where an electronic ballast is needed.

Those skilled in the art will appreciate that it is merely an application example of the cable fixing apparatus 5 that is described above. The cable fixing apparatus 5 according to the embodiment of the present patent application may also be used to fix a cable other than that from a PCBA. In addition, the PCBA 4 to which the cable 3 is connected and fixed by the cable fixing apparatus 5 according to the embodiment of the present patent application may also be applied to various devices other than an electronic ballast 1. For example, such a PCBA may be used in an electronic controller of some other type besides an electronic ballast 1.

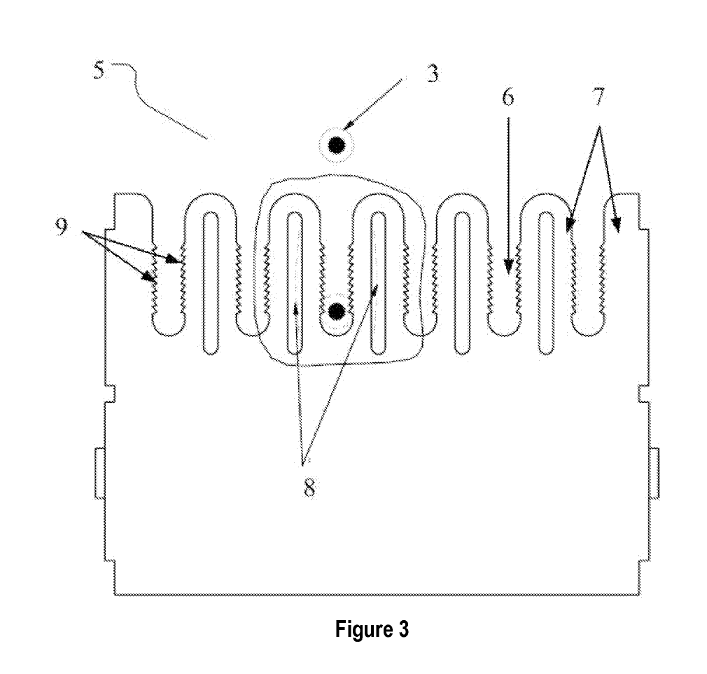

FIG. 3 illustrates the main structure of a cable fixing apparatus 5 according to an embodiment of the present patent application. The cable fixing apparatus 5 includes: at least one slot structure 6, for holding a cable 3; and clipping parts 7 at both sides of each slot structure 6, wherein at least one of the clipping parts 7 has an elasticity enhancement structure 8, and the elasticity enhancement structure 8 is configured so that the elasticity of the clipping part 7 is enhanced.

The cable fixing apparatus may include only one slot structure 6 although multiple slot structures 6 are shown in FIG. 3. It is apparent to those skilled in the art that the number of slot structures 6 can be determined according to the actual situation.

In the process of the cable 3 entering a slot structure 6, due to the presence of the elasticity enhancement structure 8, the enhanced elasticity of the clipping part 7 makes it easier for the cable 3 to enter the slot structure 6. And once the cable 3 is in the slot structure 6, because of the enhanced elasticity of the clipping part 7, the cable 3 is clipped inside the slot structure 6, and it is difficult for the cable 3 to slip out of the slot structure 6. Therefore, by using the cable fixing apparatus 5 according to the embodiments of the present patent application, the cable 3 is fixed reliably.

In the cable fixing apparatus 5 shown in FIG. 3, there is an elasticity enhancement structure 8 in each clipping part 7. However, those skilled in the art will appreciate that the elasticity enhancement structure 8 may exist only in some of the clipping parts 7. That is, it is possible that at least one of the clipping parts 7 has the elasticity enhancement structure 8.

In the cable fixing apparatus 5 shown in FIG. 3, the elasticity enhancement structure 8 is implemented in a hole-like structure in the clipping part 7. Those skilled in the art will appreciate that as an elasticity enhancement structure 8, the hole-like structure in the clipping part 7 maybe arranged in various forms other than the form shown in FIG. 3. For example, the hole-like structure may have an outline such as circular, elliptic and water drop-like. In addition, there may be multiple holes in each of the clipping parts 7, arranged in various ways, e.g., in an array or in a random distribution. Moreover, those skilled in the art will appreciate that the elasticity enhancement structure 8 may be implemented in a form other than a hole in the clipping part 7. For example, the elasticity enhancement structure 8 may be constituted by at least one portion of the clipping part 7, the thickness of which is smaller than that of portions of the clipping part 7 other than the at least one portion. The at least one portion may be formed by polishing or cutting the clipping part 7 which was already shaped with a uniform thickness, or the clipping part 7 may be directly shaped with the at least one portion by molding. It should be noted that, the difference of thickness between the at least one portion and the portions in the clipping part 7 other than the at least one portion could be properly determined by those skilled in the art according to the actual situation.

In addition, in the cable fixing apparatus 5 shown in FIG. 3, a locking structure 9 maybe provided on the clipping parts 7 on both sides of the slot structure 6. The presence of the locking structure 9 makes it even more difficult for the cable 3 held in the slot structure 6 to slip out of the slot structure 6. Moreover, the locking structure 9 is designed so that it does not block the cable 3 from entering the slot structure 6. However, those skilled in the art should appreciate that there could be no locking structure 9 on the clipping part 7.

In the cable fixing apparatus 5 shown in FIG. 3, there is a locking structure 9 in each clipping part 7. However, those skilled in the art will appreciate that the locking structure 9 may exist only in some of the clipping parts 7. That is, it is possible that at least one of the clipping parts 7 has the locking structure 9.

In the cable fixing apparatus 5 shown in FIG. 3, the clipping part 7 and the body of the cable fixing apparatus 5 are formed integrally. However, those skilled in the art will appreciate that the clipping part 7 and the body of the cable fixing apparatus 5 may also be formed separately and then assembled together.

In the cable fixing apparatus 5 shown in FIG. 3, every two adjacent slot structures 6 share the same clipping part 7. However, those skilled in the art will appreciate that it is also applicable that two adjacent slot structures 6 do not share the same clipping part 7. That is, a clipping part 7 may be for one particular slot structure 6 exclusively.

In the cable fixing apparatus 5 shown in FIG. 3, the slot structure 6 may be formed by adjacent clipping parts 7. However, those skilled in the art will appreciate that the slot structure 6 and the clipping part 7 may be independent components and assembled together.

In addition, those skilled in the art will appreciate that any combination of the various above-mentioned forms of the clipping part 7, the slot structure 6 and the elasticity enhancement structure 8 is applicable, to form a cable fixing apparatus 5 of any configuration.

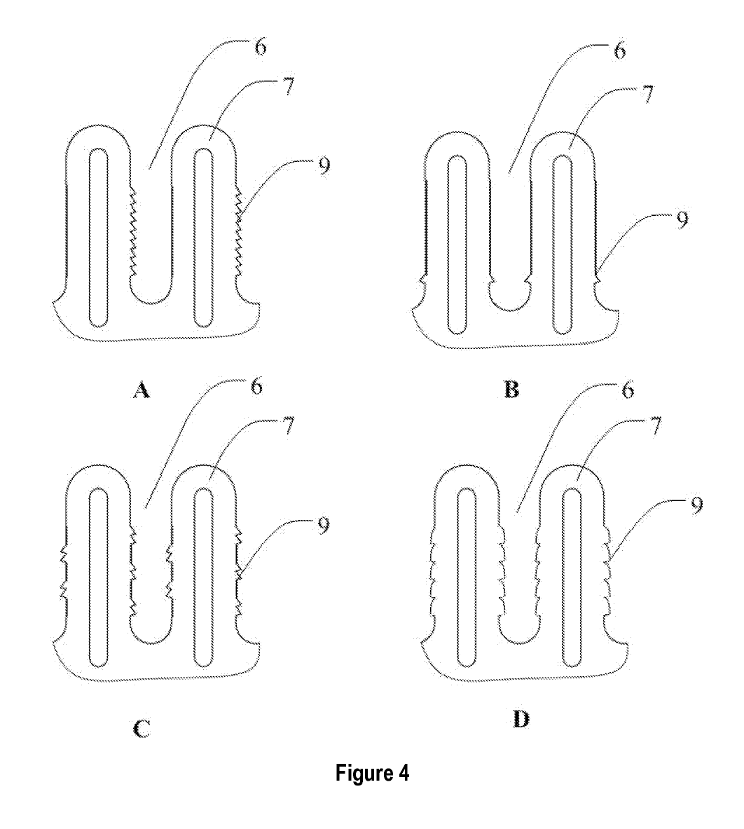

FIGS. 4A to 4D illustrate alternatives of a locking structure 9 of the cable fixing apparatus 5 according to an embodiment of the present patent application. The part shown in FIGS. 4A to 4D corresponds to the part in FIG. 3 marked with an irregular curve.

In the cable fixing apparatus 5 shown in FIG. 3, multiple locking structures 9 are provided on each of the sides of the clipping part 7 that correspond to the slot structure 6. That is, multiple locking structures 9 are provided on the clipping part 7 at both sides of the slot structure 6. However, as shown in FIGS. 4A to 4D, the locking structure 9 may be implemented in various forms other than this, making it difficult for the cable 3 held in the slot structure 6 to slip out of the slot structure 6 without blocking the cable 3 from entering the slot structure 6.

As shown in FIG. 4A, the locking structure 9 may appear on the clipping part 7 at only one side of the slot structure 6.

As shown in FIG. 4B, only one locking structure 9 may be provided on the clipping part 7 at each of the sides of the slot structure 6.

As shown in FIG. 4C, the locking structures 9 on the clipping parts 7 on both sides of the slot structure 6 may appear in an alternating manner, instead of appearing in pairs.

As shown in FIG. 4D, the locking structure 9 may have various shapes. For example, the edges of the locking structure 9 may not be a straight line. The locking structure 9 shown in FIG. 4D has curvy edges.

Those skilled in the art will appreciate, the locking structure 9 may be configured into any suitable forms other than the forms shown in FIGS. 4A to 4D, as long as they can make it difficult for the cable 3 held in the slot structure 6 to slip out of the slot structure 6 without blocking the cable 3 from entering the slot structure 6.

By using the cable fixing apparatus 5 according to the embodiments of the present patent application, the cable can be fixed

In addition, by using the cable fixing apparatus 5 according to the embodiments of the present patent application, the cable can be fixed at a relatively low cost.

In addition, as discussed above, an electronic controller such as electronic ballast having at least some of its circuit elements arranged on the PCBA 1, and a light-emitting device including and driven by the electronic ballast are also included in the scope of the present patent application.

The terms “include”, “comprise” and any other variants of them herein are inclusive, and do not exclude additional, unrecited elements of a process, method, apparatus or device, as well as those elements that are inherently included by the process, method, apparatus or device. Without further limitations, the wording “including an” element does not exclude the possibility of another identical element being present in the process, method, apparatus or device including the element.

The embodiments of the present patent application are described in detail in conjunction with the accompanying drawings. However, those skilled in the art will appreciate that the embodiments described above are for illustrating the present patent application only and do not constitute a limitation thereof. Those skilled in the art will also appreciate that various modifications, equivalents and variations may be made without deviation from the spirit and scope of the present patent application defined by the claims attached. Therefore, the scope of the present patent application shall be defined by only the claims attached and their equivalents.

Moreover, the scope of the present patent application is not limited to the specific embodiments of the processes, methods, apparatuses and devices described herein. Those skilled in the art will appreciate that, based on the disclosure of the present patent application, the process, method, apparatus or device according to the present patent application may use those elements, either existing or to be developed in the future, that carry out functions or can lead to results substantially the same as the elements disclosed in the corresponding embodiments herein. Therefore, the attached claims shall include the process, method, apparatus or device including such elements.

1. A cable fixing apparatus, comprising:
at least one slot structure, for holding a cable; and
clipping parts at both sides of each slot structure, wherein at least one of the clipping parts has an elasticity enhancement structure, and the elasticity enhancement structure is configured so that the elasticity of the clipping part is enhanced.

2. The cable fixing apparatus according to claim 1, wherein two adjacent slot structures share the same clipping part.

3. The cable fixing apparatus according to claim 1, wherein the elasticity enhancement structure is a hole-like structure arranged in the clipping part, or the elasticity enhancement structure is constituted by at least one portion of the clipping part, the thickness of which is smaller than that of portions of the clipping part other than the at least one portion.

4. The cable fixing apparatus according to claim 1, wherein at least one of the sides of at least one of the clipping parts that correspond to the slot structure has at least one locking structure, and the locking structure is configured so as to make it difficult for the cable held in the slot structure to slip out of the slot structure without blocking the cable from entering the slot structure.

5. A printed circuit board assembly comprising a cable fixing apparatus comprising: at least one slot structure, for holding a cable; and clipping parts at both sides of each slot structure, wherein at least one of the clipping parts has an elasticity enhancement structure, and the elasticity enhancement structure is configured so that the elasticity of the clipping part is enhanced, wherein a cable of the printed circuit board assembly is configured to be fixed by the cable fixing apparatus.

6. An electronic controller comprising a printed circuit board assembly comprising a cable fixing apparatus comprising: at least one slot structure, for holding a cable; and clipping parts at both sides of each slot structure, wherein at least one of the clipping parts has an elasticity enhancement structure, and the elasticity enhancement structure is configured so that the elasticity of the clipping part is enhanced, wherein in that at least some of circuit elements in the electronic controller are arranged on the printed circuit board assembly.

7. The electronic controller according to claim 6, wherein the electronic controller is an electronic ballast.

8. A light-emitting device, comprising an electronic controller, the electronic controller comprising a printed circuit board assembly, the printed circuit board assembly comprising a cable fixing apparatus comprising: at least one slot structure, for holding a cable; and clipping parts at both sides of each slot structure, wherein at least one of the clipping parts has an elasticity enhancement structure, and the elasticity enhancement structure is configured so that the elasticity of the clipping part is enhanced, wherein at least some of circuit elements in the electronic controller are arranged on the printed circuit board assembly, and wherein the electronic controller is an electronic ballast, comprising an electronic ballast for driving the light-emitting device, and the electronic ballast is configured to be an electronic ballast according to claim 7.
